(19) United States
(12) Patent Application Publication
(10) Pub. No.: US 2016/0111573 A1
(43) Pub. Date: Apr. 21, 2016

(54) HIGHLY DENSIFIED PV MODULE

(71) Applicant: TENKSOLAR, INC., Minneapolis, MN (US)

(72) Inventors: Dallas W. Meyer, Prior Lake, MN (US); Lowell J. Berg, Prior Lake, MN (US); Steven E. Wheeler, Northfield, MN (US)

(21) Appl. No.: 14/919,648

(22) Filed: Oct. 21, 2015

Related U.S. Application Data
(60) Provisional application No. 62/066,689, filed on Oct. 21, 2014.
(60) Provisional application No. 62/153,940, filed on Apr. 28, 2015.
(60) Provisional application No. 62/153,948, filed on Apr. 28, 2015.
(60) Provisional application No. 62/153,949, filed on Apr. 28, 2015.
(60) Provisional application No. 62/153,955, filed on Apr. 28, 2015.
(60) Provisional application No. 62/153,957, filed on Apr. 28, 2015.
(60) Provisional application No. 62/153,960, filed on Apr. 28, 2015.
(60) Provisional application No. 62/210,271, filed on Aug. 26, 2015.

(51) Int. Cl. H01L 31/05; G01R 31/40; H02S 40/34; H01L 31/049

(52) U.S. Cl. CPC H01L 31/0504; H01L 31/049; H02S 50/00; H02S 40/34

(57) ABSTRACT

In an example, a photovoltaic (PV) module includes multiple PV cells, a continuous backsheet, a circuit card, and a buried first polarity contact. The PV cells are arranged in rows and columns. The continuous backsheet is positioned behind the PV cells, includes a ground plane for the PV cells, and is electrically coupled between a first row and a last row of the PV cells. The circuit card is mechanically coupled to a back of the PV module and includes a first connector with a first polarity and a second connector with an opposite second polarity. The buried first polarity contact is positioned behind the PV cells, is electrically coupled to a back of each PV cell in one of the rows of the PV cells, and extends through a slot formed in the continuous backsheet to electrical contact with the first connector of the circuit card.

### CROSS-REFERENCE TO RELATED APPLICATIONS

This patent application claims the benefit of and priority to:
U.S. Provisional Patent Application Ser. No. 62/066,689, filed Oct. 21, 2014;
U.S. Provisional Patent Application Ser. No. 62/153,940, filed Apr. 28, 2015;
U.S. Provisional Patent Application Ser. No. 62/153,948, filed Apr. 28, 2015;
U.S. Provisional Patent Application Ser. No. 62/153,949, filed Apr. 28, 2015;
U.S. Provisional Patent Application Ser. No. 62/153,955, filed Apr. 28, 2015;
U.S. Provisional Patent Application Ser. No. 62/153,957, filed Apr. 28, 2015;
U.S. Provisional Patent Application Ser. No. 62/153,960, filed Apr. 28, 2015; and
U.S. Provisional Patent Application Ser. No. 62/210,271, filed Aug. 26, 2015.

The foregoing patent applications are incorporated herein by reference.

### FIELD

Example embodiments described herein relate to highly densified photovoltaic (PV) modules.

### BACKGROUND

Unless otherwise indicated, the materials described in the background section are not prior art to the claims in the present application and are not admitted to be prior art by inclusion in this section.

In the solar industry, two important features of a solar or PV module are its aperture efficiency (power output per unit area under a fixed radiation value) and its cost. Methods of increasing aperture efficiency and decreasing costs are highly valued.

FIG. 1 illustrates a conventional PV module 100 that includes a string of serially connected PV cells 102. Such conventional PV modules may have serpentine current flow 104 in which current generated by the string of serially-connected PV cells 102 of the PV module 100 zig-zags through the string of serially-connected PV cells 102, as generally illustrated in FIG. 1. Multiple such PV modules 100 may be connected in series in a PV system. Due to the serial nature of the individual PV modules 100 (e.g., due to the serially-connected PV cells 102 of each PV module 100) as well as the serial nature of the PV system (e.g., due to the serially-connected PV modules 100), a voltage potential within a given PV module 100 from its PV cells 102 to its frame and grounded metal may be as high as 1000 volts direct current (VDC) up to 1500 VDC or higher. For a transformerless inverter, a maximum potential to ground can be well over 1200 volts (V) up to 1900 V or higher. In addition, if a short develops internal to the PV module 100 or if one of the PV cell 102 is shaded, a diode resistance can cause very large amounts of power to be dissipated locally, creating hot spots.

Another issue with some conventional PV modules 100 is that they may use large PV cells 102, which may result in significant resistance loss in bus connectors between PV cells 102. Increasing a width of the bus connectors may result in increased shading loss, and increasing a thickness of the bus connectors may result in stresses during lamination that can cause the PV cells 102 to crack.

In keeping with the high voltage design of such conventional PV modules 100, an all plastic backsheet is typically used to try and ensure isolation of the high voltage from incidental contact. Such plastic backsheets may typically be constructed of Tedlar, polyethylene terephthalate (PET), or a combination of these or other high dielectric materials.

The subject matter claimed herein is not limited to embodiments that solve any disadvantages or that operate only in environments such as those described above. Rather, this background is only provided to illustrate one exemplary technology area where some embodiments described herein may be practiced.

### BRIEF SUMMARY OF SOME EXAMPLE EMBODIMENTS

Example embodiments described herein relate to highly densified photovoltaic (PV) modules.

In an example embodiment, a PV module includes multiple PV cells, a continuous backsheet, a circuit card, and a buried first polarity contact. The PV cells are arranged in rows and columns, where the rows include a first row, a last row, and one or more intermediate rows between the first and last rows. The continuous backsheet is positioned behind the PV cells and includes a ground plane for the PV cells. The continuous backsheet is electrically coupled between the first row and the last row of the PV cells. The circuit card is mechanically coupled to a back of the PV module and includes a first connector with a first polarity and a second connector with a second polarity opposite the first polarity. The buried first polarity contact is positioned behind the PV cells and is electrically coupled to a back of each PV cell in one of the rows of the PV cells. The buried first polarity contact extends through a slot formed in the continuous backsheet to electrical contact with the first connector of the circuit card.

Additional features and advantages of the invention will be set forth in the description which follows, and in part will be obvious from the description, or may be learned by the practice of the invention. The features and advantages of the invention may be realized and obtained by means of the instruments and combinations particularly pointed out in the appended claims. These and other features of the present invention will become more fully apparent from the following description and appended claims, or may be learned by the practice of the invention as set forth hereinafter.

### BRIEF DESCRIPTION OF THE DRAWINGS

To further clarify the above and other advantages and features of the present invention, a more particular description of the invention will be rendered by reference to specific embodiments thereof which are illustrated in the appended drawings. It is appreciated that these drawings depict only typical embodiments of the invention and are therefore not to be considered limiting of its scope. The invention will be described and explained with additional specificity and detail through the use of the accompanying drawings in which:

FIG. 1 illustrates a conventional PV module that includes a string of serially connected PV cells;

FIGS. 2A and 2B include a front view and an upside down perspective view of a PV module;

FIG. 3 illustrates a cross-sectional side view of the PV module of FIGS. 2A and 2B;

FIG. 4 illustrates an example embodiment of electrical interconnects between PV cells in a cell layer of the PV module of FIGS. 2A and 2B;

FIGS. 5A-5C include various detail views of some of the PV cells and the electrical interconnects of FIG. 4;

FIG. 6A is a back view of an embodiment of a continuous backsheet of the PV module of FIGS. 2A and 2B;

FIG. 6B is a back perspective view of another embodiment of the continuous backsheet of the PV module of FIGS. 2A and 2B;

FIG. 7 illustrates an example embodiment of a circuit card of the PV module of FIGS. 2A and 2B; and

FIGS. 8A-8C illustrate portions of an undermount assembly 800 that may be implemented in the PV module of FIGS. 2A and 2B.

### DETAILED DESCRIPTION OF SOME EXAMPLE EMBODIMENTS

Reference will now be made to the drawings to describe various aspects of some example embodiments of the invention. The drawings are diagrammatic and schematic representations of such example embodiments, and are not limiting of the present invention, nor are they necessarily drawn to scale.

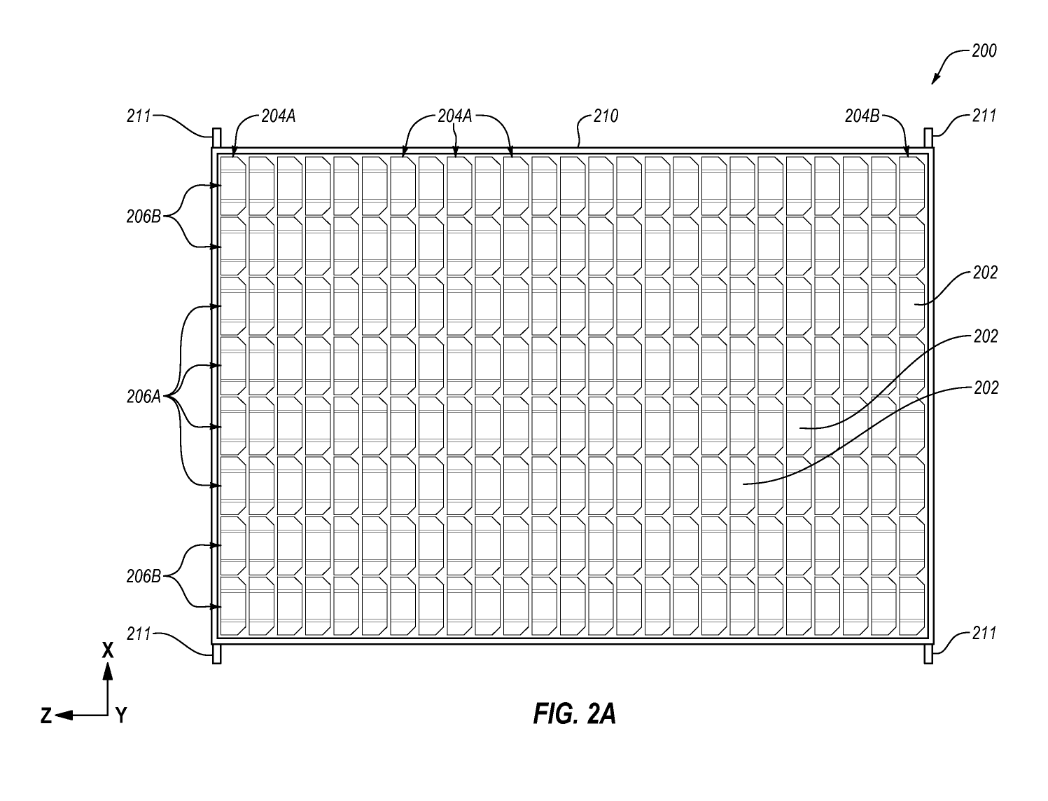

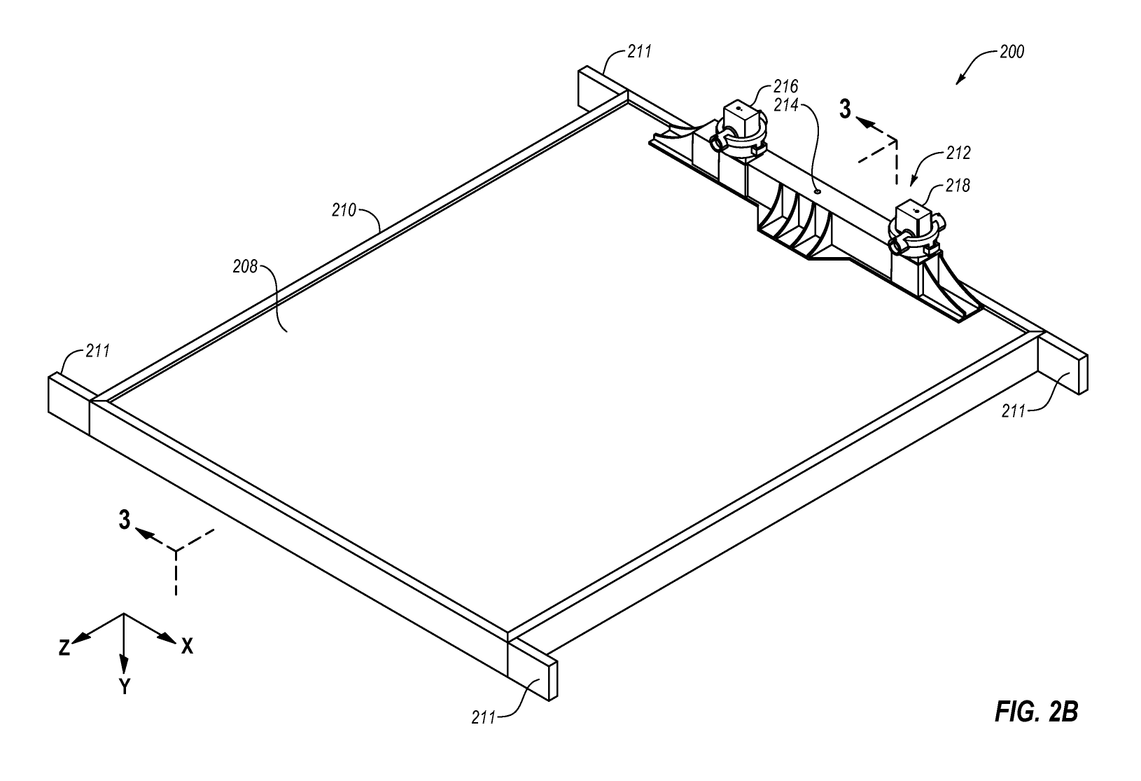

FIGS. 2A and 2B include a front view and an upside down perspective view of a PV module 200, arranged in accordance with at least one embodiment described herein. FIGS. 2A and 2B additionally include arbitrarily-defined X, Y, and Z coordinate axes which are used throughout many of the various Figures to provide a consistent frame of reference. In the discussion that follows, and unless context indicates otherwise, a “top” or “front” (or similar term) of the PV module 200 (or subcomponent thereof) refers to the positive Y side of the PV module 200 (or subcomponent) or positive Y direction, while “bottom”, “back”, or “rear” (or similar term) refers to the negative Y side or negative Y direction.

As best seen in FIG. 2A, the PV module 200 includes multiple discrete PV cells 202 arranged in rows 204 and columns 206A, 206B (collectively “columns 206”). The rows 204 specifically include a first row 204A and a last row 204B. One or more rows 204 between the first row 204A and the last row 204B may be referred to as intermediate rows. The columns 206 specifically include intermediate columns 206A and end columns 206B. The PV cells 202 in each of the rows 204 are electrically connected in parallel, while the PV cells 202 in each of the columns 206 are electrically connected in series. Accordingly, and in operation, current generally flows unidirectionally through the PV cells 202. In the example of FIG. 2A, for instance, current generally flows through all of the PV cells 202 from left to right, corresponding to the arbitrarily-defined negative Z-direction.

As best seen in FIG. 2B, the PV module 200 includes a continuous backsheet 208 positioned behind the PV cells 202. With combined reference to FIGS. 2A and 2B, the PV module 200 may include a frame 210 around a perimeter of the continuous backsheet 208 and various layers of the PV module 200 (described in greater detail below) that include the PV cells 202. The frame 210 may include frame extensions 211 disposed at the four corners of the frame 210 for use in interconnecting the PV module 200 in an array of multiple PV modules 200 and/or reflectors. Additional details regarding frame extensions and PV module arrays are disclosed in U.S. patent application Ser. No. 12/711,040 filed Feb. 23, 2010 and entitled HIGHLY EFFICIENT RENEWABLE ENERGY SYSTEM which application is herein incorporated by reference.

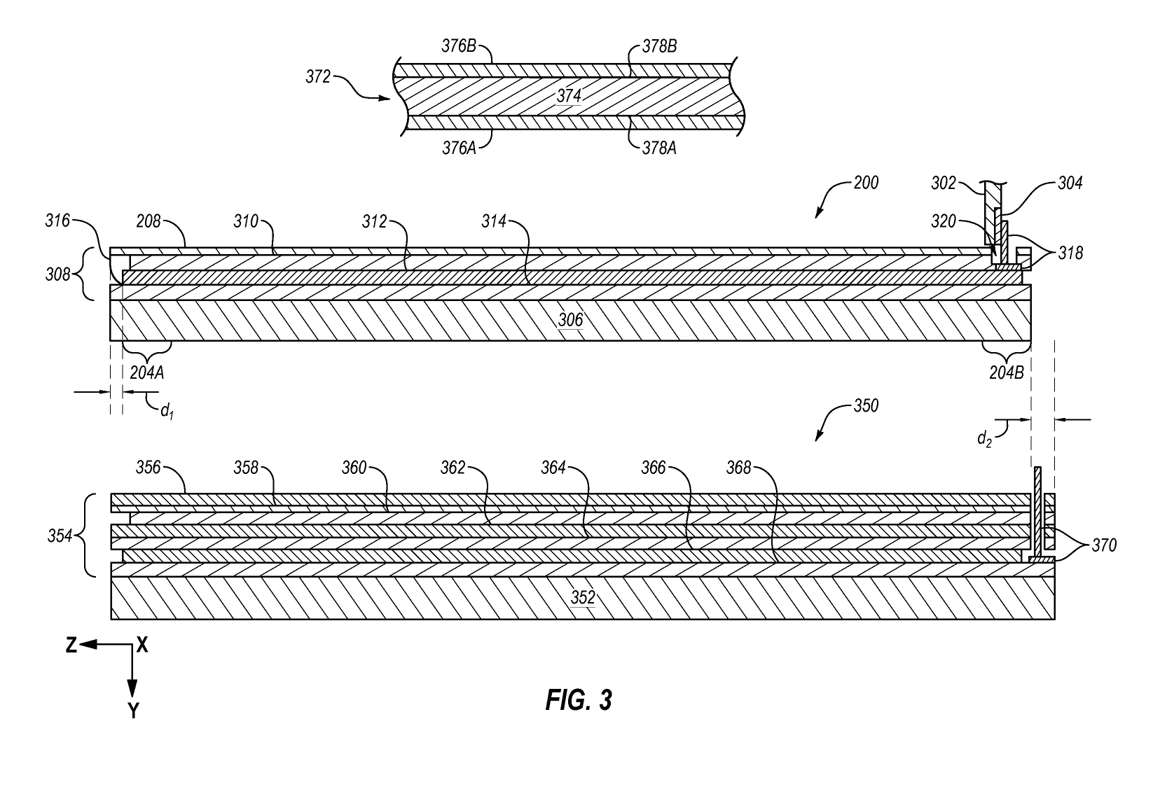

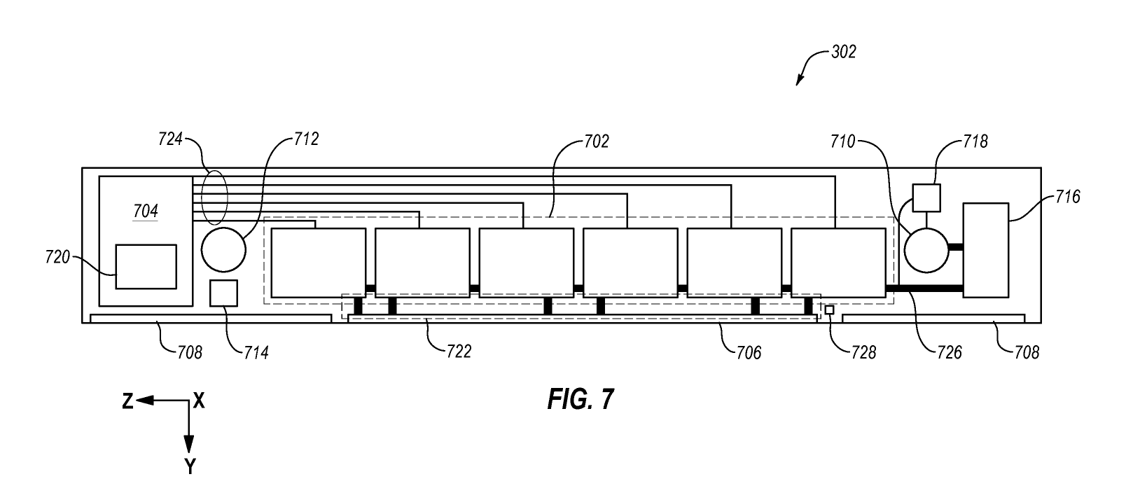

The PV module 200 additionally includes multiple converters (FIG. 7). The multiple converters are included in an undermount assembly 212 mounted to a bottom of the PV module 200 at an end thereof. FIG. 2B additionally includes cutting plane 3-3 referenced in the discussion of FIG. 3 below.

The continuous backsheet 208 in some embodiments generally extends from edge to edge of the PV module 200 and cooperates with the frame 210 and a transparent front plate (FIG. 3) of the PV module 200 to enclose the PV cells 202 of the PV module 200, protect against moisture ingress into the PV module 200, and electrically enclose a PV-generating region (e.g., the PV cells 202) with a grounded conductive material for added safety. The continuous backsheet 208 may be between 0.025 to 0.4 millimeters (mm) thick or some other thickness and includes an electrically-conductive material such as aluminum, aluminum alloy, or other suitable electrically-conductive material. Such aluminum or aluminum alloy may include a temper of hard, full hard, or extra hard, example products of which may be referred to in industry as 1145-H19, 1235-H19, and similar products. Alternately or additionally, the aluminum or aluminum alloy may include aluminum or aluminum alloy in a commercially pure wrought family such as 1000 series aluminum or containing alloying elements for improved workability, strength, or other characteristic, such as 3000, 5000, or 6000 series alloys. The designation “1000 series” on any other “series” relating to a particular aluminum alloy in the instant disclosure is a four-digit designation of a wrought aluminum alloy numbered in accordance with the International Alloy Designation System (“IADS”), introduced in about 1970 by the Aluminum Association of the United States. Other example electrically-conductive materials that may be utilized for the continuous backsheet 208 may include stainless steel or magnesium or other materials that may be optimized for low mass, strength, material cost, formability and other mechanical and physical properties.

The continuous backsheet 208 may be a ground plane for the PV cells 202 of the PV module 200. For example, the continuous backsheet 208 may be electrically coupled between a first subset of the PV cells 202 (e.g., the first row 204A of the PV cells 202) and a second subset of the PV cells 202 (e.g., the last row 204B of the PV cells 202). A buried first polarity contact (FIG. 3) between the multiple converters and the second subset of PV cells 202 may be a cathode of the PV module 200. An end connection (FIG. 3) between the continuous backsheet 208 and the first subset of PV cells 202 may be an anode of the PV module 200. In these and other embodiments, module return current may be carried by the continuous backsheet 208 from the cathode to the anode of the PV module 200.

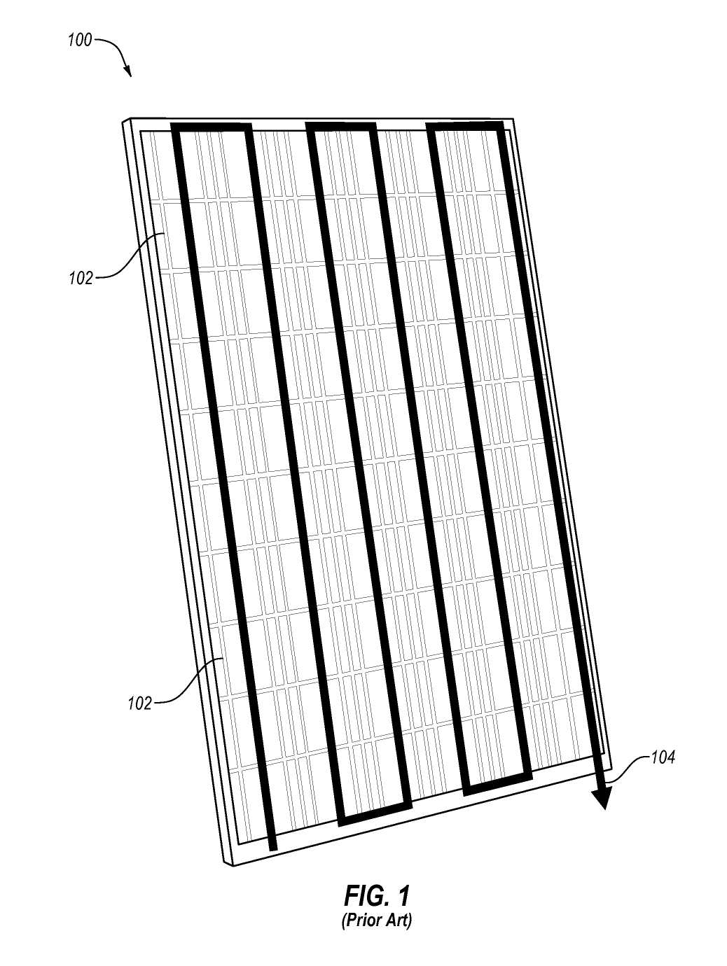

In some embodiments, the rows 204 and columns 206 of PV cells 202 include 25 rows and 8 columns of PV cells 202 such that the PV module 200 includes a total of two hundred PV cells 202. Alternatively or additionally, each of the PV cells 202 may include about half of a 156 mm by 156 mm PV cell 202. More particularly, each of the PV cells 202 may be about 156.75 mm by 78.375 mm. Under 1 sun of illumination, a power output collectively generated by the PV cells 202 in this and other embodiments may be at least 400 watts (W), such as 400 W to 600 W, and a voltage collectively generated by the PV cells 202 may be no more than 17 VDC. The voltage collectively generated by the PV cells 202 may be much lower than the voltage collectively generated by the PV cells of conventional PV modules (such as the PV module 100 of FIG. 1).

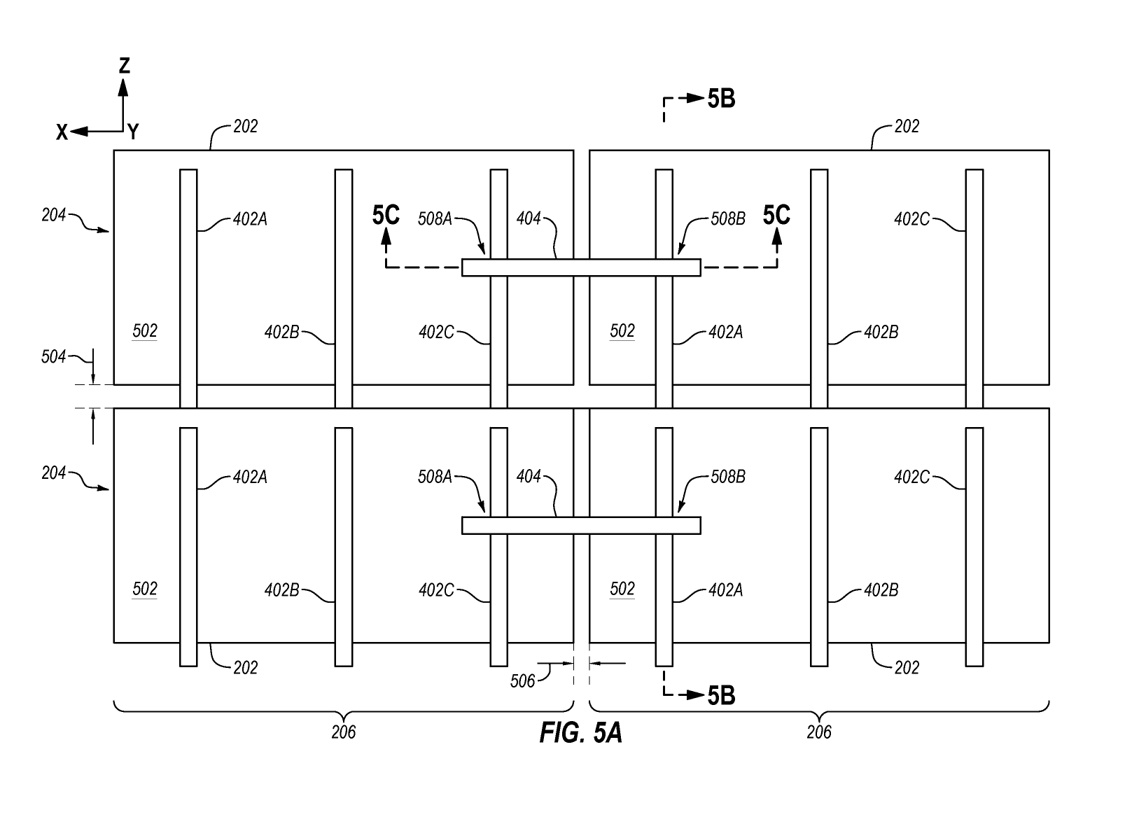

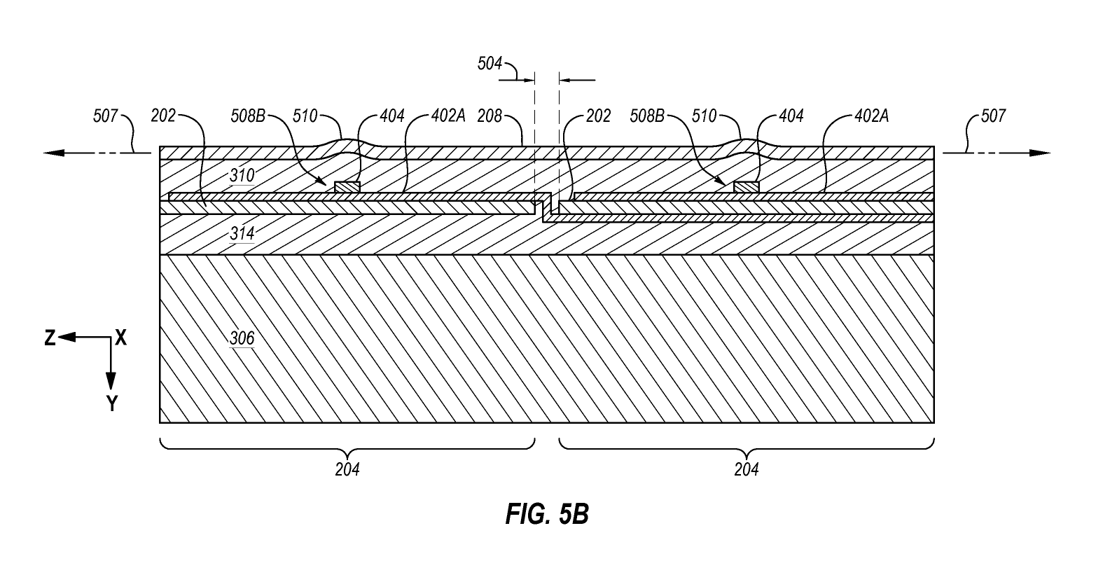

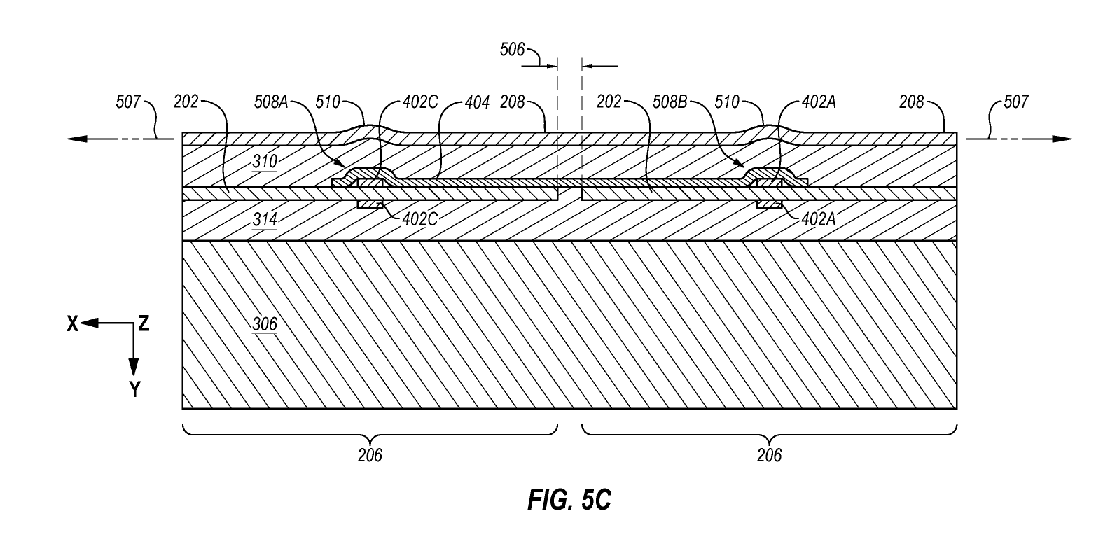

As a result of the relatively low voltage of the collective output of the PV cells 202, the PV cells 202 may have relatively narrow cell-to-cell gaps, as discussed with respect to FIGS. 5A-5C, such as not more than 1.5 mm, or in a range from 0.6 mm to 1.5 mm. The relatively narrow cell-to-cell gaps in these and other embodiments may increase an aperture efficiency of the PV module 200 compared to PV modules with wider cell-to-cell gaps.

These cell-to-cell gaps are sometimes referred to as “whitespace”, which term generally refers to areas of a PV module (such as the PV module 200) that do not directly capture and convert solar energy to electrical energy. In addition to cell-to-cell gaps, the whitespace of the PV module 200 may include cell-to-front plate edge spacings (described below) along the perimeter of the PV module 200 between edges of a front plate of the PV module 200 and edges of outermost rows 204 and columns 206 of PV cells 202. The cell-to-front plate edge spacings in the PV module 200 may be relatively narrow, which may increase the aperture efficiency of the PV module 200, as a result of the use of the continuous backsheet 208 (which may include a metal backsheet) and the relatively low voltage of the collective output of the PV cells 202. For example, the cell-to-front plate edge spacing may have a width of 14 mm or less in some embodiments.

In general, each of the columns 206 of PV cells 202 may include N PV cells 202 electrically connected together in series. For example, each of the columns 206 may include 25 PV cells 202 (or some other number of PV cells 202) electrically connected together in series. In these and other embodiments, the PV cells 202 may include PV cells 202 with different energy conversion efficiencies and/or different PV cell types. By way of example, the different energy conversion efficiencies may include 18.0%, 17.8%, 17.6%, 17.4%, or other energy conversion efficiencies and the PV cell types may include monocrystalline PV cells, polycrystalline PV cells, passive emitter rear contact (PERC) PV cells, or n-type PV cells with energy conversion efficiencies of 19-22% or greater.

The PV cells 202 of different energy conversion efficiencies or PV cell types may be grouped in the rows 206 according to energy conversion efficiency and/or PV cell type. For instance, at least one of the rows 206 may include N PV cells 202 with a first energy conversion efficiency or of a first PV cell type while at least one other of the rows 206 may include N PV cells 202 with a different second energy conversion efficiency or of a different second PV cell type. As a particular example that involves energy conversion efficiency, 4 of the 8 rows 206 (or 50% of the PV cells 202) may include PV cells 202 with 17.2% energy conversion efficiency while the remaining 4 of the 8 rows (or 50% of the PV cells 202) may include PV cells 202 with 18% energy conversion efficiency, which may be equivalent to all 8 of the rows 206 including PV cells 202 with 17.6% energy conversion efficiency. As another example that involves energy conversion efficiency, 5 of the 8 rows 206 (or 62.5% of the PV cells 202) may include PV cells 202 with 17.4% energy conversion efficiency while the remaining 3 of the 8 rows 206 (or 37.5% of the PV cells 202) may include PV cells 202 with 18.0% energy conversion efficiency, which may also be equivalent to all 8 of the rows 206 including PV cells 202 with about 17.6% energy conversion efficiency.

As a particular example that involves different PV cell types, 4 of the 8 rows 206 (or 50% of the PV cells 202) may include PV cells 202 of a polycrystalline cell type while the remaining 4 of the 8 rows (or 50% of the PV cells 202) may include PV cells 202 of a monocrystalline cell type.

The above examples include PV cells 202 of two different energy conversion efficiencies or two different PV cell types. In other embodiments, the PV cells 202 may be of three or more different energy conversion efficiencies or three or more different PV cell types. Alternatively or additionally the PV cells 202 may be of at least two different energy conversion efficiencies and at least two different PV cell types.

In these and other embodiments, the PV cells 202 of higher energy conversion efficiency may be located in an area of the PV module 200 that receives more light than an area of the PV module 200 that includes at least some of the PV cells 202 of lower energy conversion efficiency. For example, when the PV module 200 is implemented in a PV system with alternating rows of PV modules and reflectors (or concentrators), the PV module 200 may be aligned to the sun (e.g., angled facing south in the Northern Hemisphere or north in the Southern Hemisphere). Columns 206 in the lower (e.g., negative X direction) half of the PV module 200 may receive more light than columns in the upper (e.g., positive X direction) half of the PV module 200. Thus, columns 206 in the lower half of the PV module 200 may include PV cells 202 with a first energy conversion efficiency while columns 206 in the upper half of the PV module 200 may include PV cells 202 with a second energy conversion efficiency that is lower than the first energy conversion efficiency.

Alternatively, to allow the PV module 200 to be reversible, the PV cells 202 with the first energy conversion efficiency may be located in a middle of the PV module 200, e.g., in the intermediate rows 206B, while the PV cells 202 with the second energy conversion efficiency may be located at top and bottom of the PV module 200, e.g., in the end rows 206B. In this example, when the PV module 200 is implemented in a PV system with alternating rows of PV modules and reflectors, the intermediate rows 206A may receive more light than at least the end rows 206B at the top of the PV module 200.

Some PV systems include rows of PV modules 200 that are aligned to the south that alternate with rows of PV modules 200 that are aligned to the north. In such PV systems, the rows of PV modules 200 that are aligned to the south in the Northern Hemisphere (or to the north in the Southern Hemisphere) may receive more light than the PV modules 200 that are aligned to the north in the Northern Hemisphere (or to the south in the Southern Hemisphere). As such, the PV modules 200 in the rows that are aligned to the south in the Northern Hemisphere (or to the north in the Southern Hemisphere) may include PV cells 202 with higher energy conversion efficiency than the PV cells 202 included in the PV modules 200 that are aligned to the north in the Northern Hemisphere (or to the south in the Southern Hemisphere).

Optionally, and with reference to FIG. 2B, the PV module 200 may further include a light emitting diode (“LED”) 214 or other optical signal source viewable from the rear of the PV module 200. The LED 214 is illustrated in FIG. 2B as being located on a bottom surface of the undermount assembly 212 and may alternatively be located on any other surface of the undermount assembly 212 or on the rear surface or other surface of the PV module 200 where the LED 214 may be viewable during installation of the PV module 200 in a PV system. In some embodiments, the LED 214 may be configured to selectively emit optical signals in one of at least two different colors to convey status information. The different colors can include high contrast colors, e.g., colors that are relatively to easy to distinguish from each other. For instance, the different colors can include red and green, or orange and blue, or other colors that are easily distinguishable from each other.

The LED 214 may permit status information regarding the PV module 200 to be optically communicated to a viewer and/or a device including an optical receiver. The status information may be communicated in binary codes, using different colors, and/or in other suitable format. Such status information may be stored at least initially in an electronically erasable and programmable readonly memory (“EEPROM”) or other suitable storage medium of undermount assembly 212 before being communicated. Status information may include, for example, current power, periodic power profiles (e.g., by minute, hour, or the like) for a predetermined preceding time period (e.g., 24 hours), stopping and/or starting times, cumulative energy produced per day, temperature, out-of-range voltage data, ground fault detection data, module fault data, insufficient illumination data, FW revision, current operating power, system voltage, PWM value, panel voltage, high and low side current, or the like. Alternatively or additionally, the status information may indicate when the PV module 200 is connected to positive and negative DC bus leads of a module-to-module bus that electrically couples multiple PV modules 200 in parallel in a PV system.

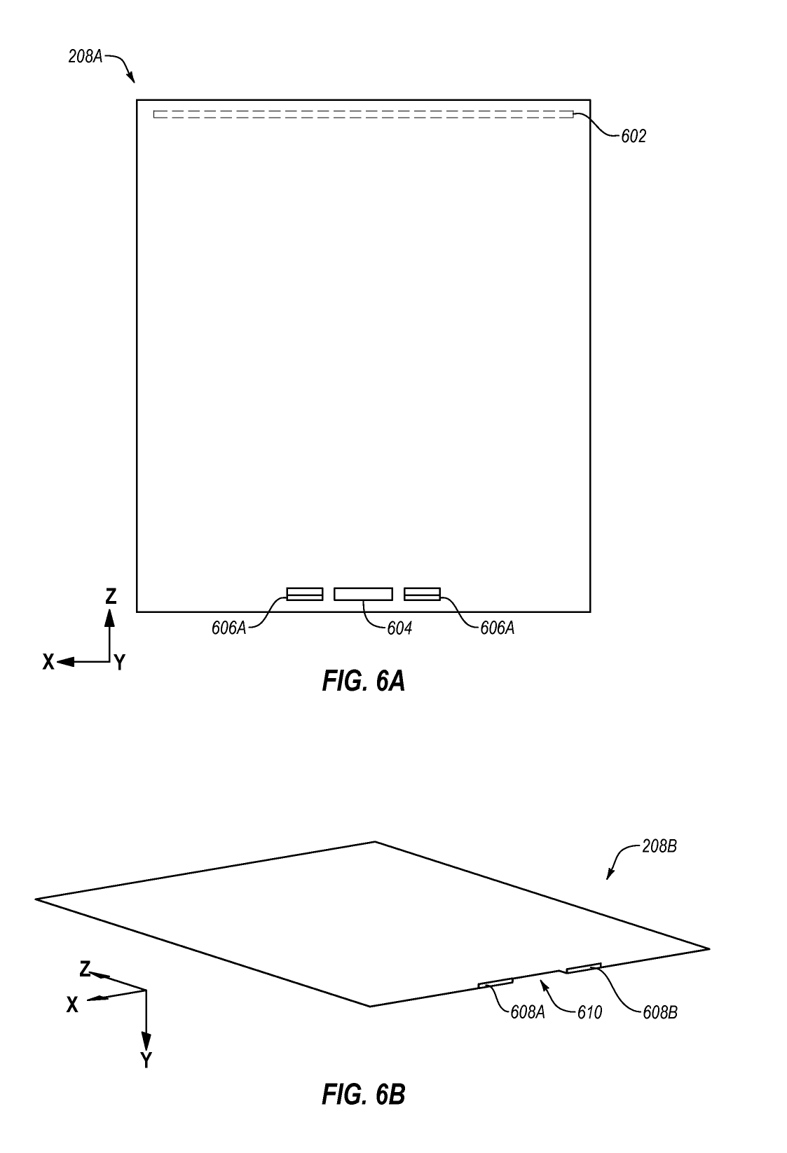

FIG. 3 illustrates a cross-sectional side view of the PV module 200 at cutting plane 3-3 in FIG. 2B, arranged in accordance with at least one embodiment described herein. Most of the undermount assembly 212 of FIG. 2B has been omitted from FIG. 3, except for a portion of a circuit card 302 that may be included in the undermount assembly 212. The circuit card 302 may be mechanically coupled to the back of the PV module 302 either directly or indirectly through one or more portions of the undermount assembly 212. As illustrated, the circuit card 302 includes a first connector 304 with the first polarity. The circuit card 302 additionally includes a second connector (FIG. 7) with a second polarity that is opposite the first polarity. For example, in the circuit card 302, the first connector 304 may include a positive connector and the second connector may include a negative connector, or vice versa. The continuous backsheet 208 may be electrically coupled to the second connector through a second polarity contact (FIGS. 6A and 6B). The second polarity contact may include a tab of the continuous backsheet 208 or other conductive element that extends from the continuous backsheet 208 to the second connector of the circuit card 302.

The PV module 200 includes a front plate 306 and layers 308. The layers 308 include the continuous backsheet 208, a first adhesive layer 310, a cell layer 312, and a second adhesive layer 314.

The cell layer 312 may include the PV cells 202 (FIG. 2A) that collectively form the cell layer 312.

The front plate 306 is disposed in front of the cell layer 312 and may be transparent or substantially transparent to at least some wavelengths of light to allow at least some wavelengths of solar radiation to pass therethrough and reach the PV cells 202 within the cell layer 312. In some embodiments, the front plate 306 includes glass. In these and other embodiments, the front plate 306 may have dimensions suitable for producing with the length direction (e.g., Z direction) across a standard width (e.g., 2.2 meters (m) or less) glass manufacturing line and/or to minimize glass waste. For instance, in the embodiment described above in which the PV cells 202 of the cell layer 312 are arranged in 25 rows 204 and 8 columns 206 and where each of the PV cells 202 is about 156.75 mm by 78.375 mm and/or in other embodiments, the front plate 306 may have a length in a range between 1990 mm to 2020 mm and a width (e.g., in the X direction) in a range between 1265 mm to 1300 mm.

The first adhesive layer 310 may couple the continuous backsheet 208 to the cell layer 312. The second adhesive layer 314 may couple the cell layer 312 to the front plate 306. As such, the second adhesive layer 314 is disposed in front of the cell layer 312 and may be transparent or substantially transparent to at least some wavelengths of light to allow at least some wavelengths of solar radiation to pass therethrough and reach the PV cells 202 within the cell layer 312. Each of the first and second adhesive layers 310 and 314 may include an adhesive material. For instance, each of the first and second adhesive layers 310 and 314 may include ethylene-vinyl acetate (EVA) or other suitable adhesive.

As illustrated in FIG. 3, an edge of the front plate 306 may extend beyond an edge of the cell layer 312 by a cell-to-front plate edge spacing d₁. Insofar as each of the front plate 306 and the cell layer 312 is generally rectangular, each may have four edges. The four edges of the front plate 306 may each extend beyond a corresponding one of the four edges of the cell layer 312 by a corresponding cell-to-front plate edge spacing. The four cell-to-front plate edge spacings, including d₁, may each be less than or equal to 14 millimeters (mm), such as in a range from 10 mm to 14 mm, or even less than 10 mm. The relatively narrow cell-to-front plate edge spacing in the PV module 202 compared to conventional PV modules is possible due to the relatively low voltage collectively generated by the PV cells 202. In conventional PV modules where the PV cells collectively generate much higher voltage (e.g., 1500 VDC), the cell-to-front plate spacing may have to be larger than 14 mm to avoid the PV cells shorting out or developing high resistance leakage paths (from moisture absorption) to a frame of the PV module.

The PV module 200 additionally includes an end connection 316 and a buried first polarity contact 318. The end connection 316 electrically couples one end of the continuous backsheet 208 to a front surface of each of the PV cells 202 (FIGS. 2A and 2B) in the first row 204A of PV cells 202.

The buried first polarity contact 318 electrically couples a back surface of each PV cell 202 in the last row 204B of PV cells 202 to the first connector 304 of the circuit card 302 and to the converters of the circuit card 304 through the first connector 304. The buried first polarity contact 318 may have an opposite polarity to the second polarity contact (FIGS. 6A and 6B) that electrically couples the continuous backsheet 208 to the second contact (FIG. 7) of the circuit card 302. For example, the buried first polarity contact 318 may include a positive contact if the second polarity contact is a negative contact or a negative contact if the second polarity contact is a positive contact. The buried first polarity contact 318 may be directly soldered to a rear surface of each of the PV cells 202 in the last row 204B, all of which may be of the same polarity. A reverse order may be applied where the PV cells 202 include n-type cells.

The buried first polarity contact 318 is a buried contact, meaning the buried first polarity contact 318 is positioned behind one of the rows 204 (e.g., the last row 204B) of PV cells 202 to improve aperture efficiency of the PV module 200 compared to PV modules that lack a buried contact. In particular, the buried first polarity contact 318 is positioned behind the last row 204B (or some other row or rows 204) of PV cells 202. A first polarity contact that is displaced from the cell layer 312 in the X and/or Z directions increases whitespace of a corresponding PV module, which whitespace includes all areas of PV modules that cannot capture sunlight. As compared to such a first polarity contact, the buried first polarity contact 318 is positioned behind one or more rows 204 of the PV cells 202 in the cell layer 312 such that the buried first polarity contact 318 is not displaced form the cell layer 312 in the X or Z directions, thereby decreasing whitespace and increasing aperture efficiency of the PV module 200 compared to PV modules with X- or Z-axis displaced first polarity contacts.

The buried first polarity contact 318 is electrically coupled to a back of each PV cell 202 in the last row 204B of PV cells 202. The buried first polarity contact 318 extends rearward from the cell layer 312 through a slot 320 formed in one or both of the continuous backsheet 208 and the first adhesive layer 310 to electrical contact with the first connector 304 of the circuit card 302. The buried first polarity contact 318 may span, in the X direction, all or at least some of the PV cells 202 within the last row 204B of PV cells 202. The buried first polarity contact 318 may include one or more electrically-conductive elements, such as electrically-conductive foil or strips, electrically-conductive tape, or other suitable material.

Conventional PV modules, such as the PV module 100 of FIG. 1, may be unable to use buried contacts. In particular, a bus connector that connects ends of serial string columns of PV cells has to connect to opposite sides of two adjacent PV cells in the two columns for the two columns to be electrically coupled in series. If a buried contact were used, it may short to one of the two columns of PV cells, rendering such a conventional PV module inoperable.

FIG. 3 additionally illustrates a PV module 350 that lacks a buried contact. The PV module 350 includes a front plate 352 and layers 354. The front plate 352 may be analogous to the front plate 306 of the PV module 200. The layers 354 of the PV module 350 may include a first electrical isolation layer 356, a continuous backsheet 358, a first adhesive layer 360, a second electrical isolation layer 362, a second adhesive layer 364, a cell layer 366, and a third adhesive layer 368.

The first electrical isolation layer 356 may include polyethylene (PE), PET, Tedlar, polyvinylidene fluoride (PVDF), or other suitable electrical isolation layer and may electrically isolate (e.g., insulate) a back surface of the continuous backsheet 358.

The continuous backsheet 358 may be analogous to the continuous backsheet 208 of the PV module 200 and may be coupled between first and last rows of PV cells in the cell layer 366 and may serve as a ground plane and/or current return path between the first and last rows of PV cells in the cell layer 366.

The first, second, and third adhesive layers 360, 364, and 368 may include EVA or other suitable adhesive. The first adhesive layer 360 may couple the continuous backsheet 358 to the second electrical isolation layer 362. The second adhesive layer 364 may couple the second electrical isolation layer 362 to the cell layer 366. The third adhesive layer 368 may couple the cell layer 366 to the front plate 352.

The second electrical isolation layer 356 may include PE, PET, Tedlar, or other suitable electrical isolation layer and may electrically isolate (e.g., insulate) the continuous backsheet 358 and the cell layer 366 from each other.

The cell layer 366 may be analogous to the cell layer 312 of the PV module 200. For purposes of comparison, it may be assumed that the cell layer 366 in the PV module 350 has identical dimensions (at least in the X and Z directions) to the cell layer 312 of the PV module 200.

The PV module 350 may additionally include an end connection (not shown) and circuit card (not shown) that are respectively analogous to the end connection 316 and the circuit card 302 of the PV module 200. In addition, the PV module 350 may include a first polarity contact 370 that is analogous in function to the buried first polarity contact 318 of the PV module 200. In particular, the first polarity contact 370 may electrically couple a back surface of each PV cell in the last row of PV cells of the cell layer 366 to a first connector (not shown) of the circuit card of the PV module 350 and to converters (not shown) of the circuit card through the first connector. Structurally, however, the first polarity contact 370 is different than the buried first polarity contact 318 since it is not located behind any rows of PV cells in the cell layer 366. Instead, the first polarity contact 370 is displaced in the negative z direction from a negative Z end of the cell layer 366, which increases an overall length and whitespace of the PV module 350 compared to the PV module 200 by an aperture distance d₂. The reduction in Z length of the PV module 200 by the aperture distance d₂ compared to the PV module 350 decreases the whitespace and increases the aperture efficiency of the PV module 200 compared to the PV module 350.

FIG. 3 additionally illustrates a detail cross-sectional side view 372 of a portion of the continuous backsheet 208, arranged in accordance with at least one embodiment described herein. As illustrated in the detail view 372 of FIG. 3, the continuous backsheet 208 may include a conductive substrate 374 and an electrical isolation layer 376A or 376B (collectively “electrical isolation layers 376”) formed on at least one of a front surface 378A or a rear surface 378B of the conductive substrate 374.

The conductive substrate 374 may include any of the electrically-conductive materials mentioned previously for the continuous backsheet 208, including aluminum, aluminum alloy, stainless steel, magnesium, or other electrically-conductive materials. Alternately or additionally, the conductive substrate 374 may have a thickness (e.g., in the Y direction) between 0.04 mm and 0.2 mm. In these and other embodiments, each of the electrical isolation layers 376 may have a thickness (e.g., in the Y direction) between 10 micrometers (μm) and 100 μm. Alternatively or additionally, each of the electrical isolation layers 376 may extend edge to edge on the front or rear surface 378A or 378B of the conductive substrate 374 and/or may be applied along one or more edges of the conductive substrate 374 for added electrical isolation along the edges of the conductive substrate 374.

Each of the electrical isolation layers 376 may include at least one of PVDF, PE, an anodize coating, or other suitable electrical isolation layer. In some embodiments, one or both of the electrical isolation layers 376 may include an ultraviolet (UV) stabilizer. Alternatively or additionally, each of the electrical isolation layers 376 may be applied directly to the conductive substrate 374 by spraying, dipping, roll coating, co-extruding, or other suitable direct application method. One or both of the electrical isolation layers 376 may be baked to minimize outgassing from the electrical isolation layers 376. For example, the electrical isolation layer 376A may be baked onto the front surface 378A of the conductive substrate 374 to minimize outgassing from the electrical isolation layer 376A into an interior of the PV module 200.

In some embodiments, the electrical isolation layer 376B may electrically isolate the rear surface 378B of the conductive substrate 374 while the electrical isolation layer 376A may electrically isolate the front surface 378B of the conductive substrate 374 from the cell layer 312. Accordingly, the electrical isolation layers 376 may be functionally analogous to the first and second electrical isolation layers 356 and 362 of the PV module 350. The first and second electrical isolation layers 356 and 362 of the PV module 350 may include cast monolithic plastic films that may require separate adhesive layers (e.g., the first and second adhesive layers 360 and 364) for lamination together with the continuous backsheet 358 and the cell layer 366. In comparison, the electrical isolation layers 376 may be formed directly on the front and rear surfaces 378A and 378B of the conductive substrate 374 without using cast plastic films that require separate adhesive for attachment.

Compared to the layers 354 of the PV module 350, the layers 308 of the PV module 200 may be about half as thick (e.g., in the Y direction). As a result, the PV module 200 may run cooler than the PV module 350 since the layers 308 of the PV module 200 may provide less thermal insulation to the cell layer 312 than the layers 354 of the PV module 350 provide to the cell layer 366. The reduction in materials in the layers 308 compared to the layers 354 may result in the PV module 200 being lighter and thinner (e.g., in the Y direction) than the PV module 350, which may reduce shipping costs per PV module 200.

In addition, the PV module 200 may have better fire or heat resistance than the PV module 350. In particular, the three adhesive layers 360, 364, and 368 of the PV module 350 may soften and deteriorate when exposed to fire and/or heat, resulting in the PV module 350 falling apart. The PV module 200 has fewer adhesive layers (only two as compared to three) so there is less to loosen and fall apart as the adhesive layers 310 and 314 soften and deteriorate.

The electrical isolation layers 376 may be thin enough that electrical connections to the continuous backsheet 208 may be made by welding directly through the electrical isolation layers 376 to the conductive substrate 374. For example, the end connection 316, which is an example of a first electrical connector, may be welded to the front surface 378A (or the rear surface 378B) of the conductive substrate 374 through the electrical isolation layer 376A (or through the electrical isolation layer 376B). As another example, a second electrical connector that electrical couples the continuous backsheet 208 to the circuit card 302 (e.g., the second polarity contact discussed above) may be welded to the rear surface 378B (or the front surface 378A) of the conductive substrate 374 through the electrical isolation layer 376B (or through the electrical isolation layer 376A).

Although illustrated in FIG. 3 as including two electrical isolation layers 376 respectively formed directly on a corresponding one of the front surface 378A or the rear surface 378B, in other embodiments, the conductive substrate 374 may include only one of the two electrical isolation layers 376 form directly on only one of the front surface 378A or the rear surface 378B. For example, only the electrical isolation layer 376A may be formed directly on the front surface 378A without forming the electrical isolation layer 376B directly on the rear surface 378B. Instead, a cast plastic film electrical isolation layer, such as the first electrical isolation layer 356 of the PV module 350, may be laminated to the rear surface 378B of the conductive substrate 374.

The electrical isolation layers 376 may have any of a variety of colors. To maximize energy production by the PV cells 202 in the cell layer 312, the electrical isolation layer 376A formed directly on the front surface 378A may be, e.g., white or transparent. When white, the electrical isolation layer 376A may scatter light incident on whitespace of the PV module 200 that is not initially incident on a front surface of any of the PV cells 202. At least some of the scattered light may be prevented from exiting through the front plate 306 by total internal reflection and may be reflected one or more times until it is incident on a front surface of one of the PV cells 202. When transparent, light incident on whitespace of the PV module 200 that is not initially incident on a front surface of any of the PV cells 202 may be reflected by the conductive substrate 374. At least some of the reflected light may be prevented from exiting through the front plate 306 by total internal reflection and may be reflected one or more times until it is incident on a front surface of one of the PV cells 202.

In other embodiments, the electrical isolation layer 376A formed directly on the front surface 378A may be, e.g., black, to reduce scattered and/or reflected whitespace light for aesthetic reasons. Alternatively or additionally, a color of the electrical isolation layer 376A on the front surface 378A of the conductive substrate 374 may be different than a color of the electrical isolation layer 376B on the rear surface 378B of the conductive substrate 374.

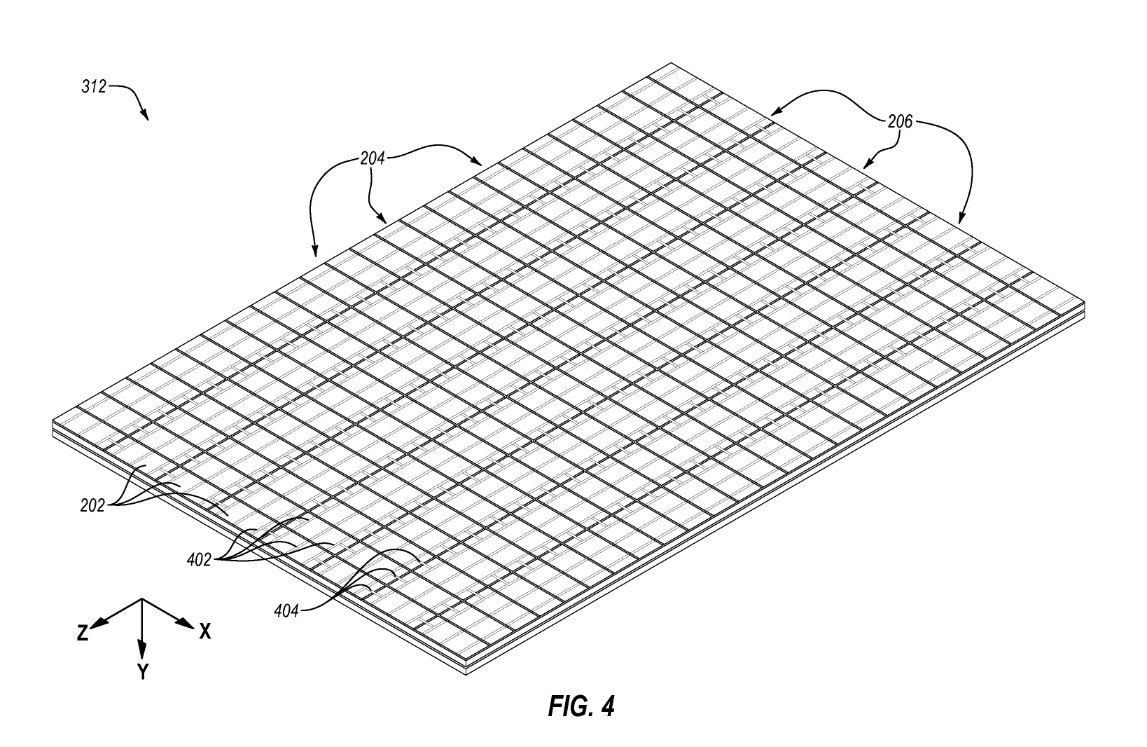

FIG. 4 illustrates an example embodiment of electrical interconnects between the PV cells 202 in the cell layer 312 of the PV module 200, arranged in accordance with at least one embodiment described herein. The electrical interconnects include busbars 402 and discrete conductive strips 404. In more detail, within each of the columns 206 of the PV cells 202, adjacent PV cells 202 may be electrically coupled together in series by one or more busbars 402. In particular, each of the busbars 402 generally extends across a front of one PV cell 202 and wraps around to extend across a rear of an adjacent PV cell 202 to electrically couple the two PV cells in series front-to-rear. In the illustrated embodiment and within each of the columns 206, three busbars 402 electrically couple each adjacent pair of PV cells 202 together in series.

Within each of the rows 204 of PV cells 202, adjacent PV cells 202 may be electrically coupled together in parallel by one or more discrete conductive strips 404 and/or an electrically-conductive material that coats a rear surface of each of the PV cells 202. Each of the discrete conductive strips 404 may span a single cell-to-cell gap in the X direction and may generally extend between adjacent busbars 402 of the adjacent PV cells 202. For example, each of the discrete conductive strips 404 may extend from a busbar 402 near one edge of a corresponding PV cell 202 across a cell-to-cell gap to a nearest corresponding busbar 402 of an adjacent corresponding PV cell 202. In the illustrated embodiment and within each of the rows 204, a single discrete conductive strip 404 and the electrically-conductive material that coats rear surfaces of each PV cell 202 in each adjacent pair of PV cells 202 electrically couple each adjacent pair of PV cells 202 together in parallel.

In some embodiments, each of the discrete conductive strips 404 may include conductive tape spanning between adjacent PV cells 202 but not continuous across an entire one or more of the PV cells 202. The conductive tape may include copper foil backing or another foil backing The electrically-conductive material may include aluminum paste or other electrically-conductive paste applied to the rear surface of each of the PV cells 202.

In comparison, some PV modules with rows of parallel-connected PV cells implement a continuous electrically-conductive strip that spans all or more of an entire row of PV cells and is electrically coupled to a rear surface of all of the PV cells in the row. During assembly, the cell layer of such a PV module may be placed on top of an adhesive layer. Within each row of PV cells in the cell layer, a continuous electrically-conductive strip may be heat-attached (e.g., by soldering) to rear surfaces of all PV cells in the row. The use of heat may melt the adhesive layer in front of the cell layer during this assembly process unless care is taken.

The embodiments described herein may use one or more discrete conductive strips 404 between each two adjacent PV cells 202 in each row 204 to form parallel electrical connections within each row 204. When the discrete conductive strips 404 are implemented as discrete pieces of conductive tape, the discrete conductive strips 404 may be applied without heat to allow assembly directly on the adhesive layer in front of the cell layer 312 without concern about melting the adhesive layer. Alternatively or additionally, the use of discrete conductive strips 404 may reduce materials costs as a sum of the lengths of all discrete conductive strips 404 within each of the rows 204 may be less than the length of the continuous electrically-conductive strip described previously. Alternatively or additionally, from a process standpoint, it may be easier to apply the discrete conductive strips 404 (which are relatively short and easy to handle) individually between each of two adjacent PV cells 202 in each row 204 than to apply a single conductive strip that spans the entire row 204 (and which may be relatively long and difficult to handle). In addition, pressure control may not be needed when applying the discrete conductive strips 404 since subsequent lamination steps (e.g., laminating the front plate 306 and layers 308 of FIG. 3 together) may include application of a relatively large pressure, which may complete a tape bonding process of the discrete conductive strips 404 to the PV cells 202 and/or busbars 402.

FIGS. 5A-5C include various detail views of some of the PV cells 202 and the electrical interconnects therebetween, arranged in accordance with at least one embodiment described herein. In more detail, FIG. 5A includes a front view of four PV cells 202 and their electrical interconnects, FIG. 5B includes a cross-sectional side view through a portion of the PV module 200 that includes two of the four PV cells 202 of FIG. 5A at cutting plane 5B-5B, and FIG. 5C includes another cross-sectional side view through a portion of the PV module 200 that includes two of the four PV cells 202 of FIG. 5A at cutting plane 5C-5C. In the view of FIG. 5B, two PV cells 202 within the same column 206 are illustrated, with rows 204 of PV cells 202 coming in and out of the page (e.g., in the positive and negative X direction). In the view of FIG. 5C, two PV cells 202 within the same row 204 are illustrated, with columns 206 of PV cells 202 coming in and out of the page (e.g., in the positive and negative Z direction).

In FIG. 5A, each of the PV cells 202 is coated with electrically conductive material 502, e.g., aluminum paste, as described with respect to FIG. 4.

As illustrated in FIGS. 5A-5C, the busbars 402 may include, for each serially adjacent pair of PV cells 202 in each of the columns 206, a left busbar 402A that is laterally to one side (e.g., left of center) of the serially adjacent pair, a middle busbar 402B, and a right busbar 402C that is laterally to the other side (e.g., right of center) of the adjacent pair. Other arrangements are possible.

As illustrated in FIGS. 5A and 5B, adjacent cells 202 within each column 206 may have a cell-to-cell gap 504. As illustrated in FIGS. 5A and 5C, adjacent cells 202 within each row 204 may have a cell-to-cell gap 506. As mentioned previously, and as a result of the relatively low voltage of the collective output of the PV cells 202, the cell-to-cell gaps 504 and 506 may be less than or equal to 1.5 mm, or in a range from 0.6 mm to 1.5 mm.

As illustrated in FIG. 5B and generally described with respect to FIG. 4, the left busbar 402A generally extends across and is coupled to a rear surface of the left-most PV cell 202 and wraps around to generally extend across and be coupled to a front surface of the adjacent right-most PV cell 202. The left busbar 402A may be soldered to the rear surface (and the electrically conductive material 502) of the left-most PV cell 202 and to the front surface of the right-most PV cell 202. The left busbar 402A may have a thickness (e.g., in the Y direction) of about 0.2 mm, or some other thickness. All busbars 402 that serially connect adjacent PV cells 202 within each column 206 may be similarly configured.

Portions of two of the discrete conductive strips 404 are also visible in FIG. 5B. As illustrated, the discrete conductive strips 404 are positioned behind the busbars 402A.

As illustrated in FIG. 5C and generally described with respect to FIG. 4, the discrete conductive strip 404 spans a single cell-to-cell gap 504 in the X direction and generally extends from the right busbar 402C on a rear surface of the left-most PV cell 202 to the left busbar 402A on a rear surface of the adjacent right-most PV cell 202. The discrete conductive strip 404 may extend past the left busbar 402C in the positive X direction and/or past the right busbar 402A in the negative X direction. The discrete conductive strip strip 404 may have a thickness (e.g., in the Y direction) of between 0.05 mm to 0.2 mm, or some other thickness. All discrete conductive strips 404 that electrically connect between left and right busbars 402A and 402C of adjacent PV cells 202 within each row 204 and between the electrically-conductive material 502 that coats rear surfaces of the adjacent PV cells 202 may be similarly configured.

When the PV module 200 is assembled, the continuous backsheet 208 may have tension 507 in the XZ plane. The tension 507 may be between 50 mega Pascals (MPa) to 100 MPa, or some other value. A joint 508A may be formed where the discrete conductive strip 404 crosses behind the right busbar 402C and a joint 508B may be formed where the discrete conductive strip 404 crosses behind the left busbar 402A. Bumps 510 may form in the continuous backsheet 208 above the joints 508A, 508B when the various layers of the PV module 200 are laminated together. An out-of-plane force at the bumps 510 as a result of the tension 507 may be four pounds per joint 508A, 508B for tension 507 of 100 MPa. Thus, the continuous backsheet 208 may apply a pressure of at least four pounds per joint 508A, 508B.

When the discrete conductive strips 404 include conductive tape, the pressure applied to the joints 508A, 508B by the continuous backsheet 208 may enhance the reliability of the electrical connection between the discrete conductive strips 404 and the busbars 402. In particular, in an absence of the pressure applied by the continuous backsheet 208, the discrete conductive strips 404 may have a tendency to peel away from or otherwise decouple from the busbars 402 over long periods of time and/or environmental cycling (e.g., changes in temperature over time), which may increase an electrical resistance between the discrete conductive strips 404 and the busbars 402. The pressure applied to the joints 508A, 508B by the continuous backsheet 208 may enhance reliability by keeping the discrete conductive strips 404 in good electrical contact with the busbars 402.

FIG. 6A is a back view of an embodiment 208A of the continuous backsheet 208, hereinafter “continuous backsheet 208A”, arranged in accordance with at least one embodiment described herein. In the illustrated embodiment, the continuous backsheet 208A includes a ground strip 602 mechanically and electrically coupled to the continuous backsheet 208A at one end of the continuous backsheet 208A. The ground strip 208A may be included as part of or correspond to the end connection 316 of FIG. 3.

The ground strip 602 may include copper, hot-dipped copper, tin-coated copper, or other electrically-conductive and solderable material. The ground strip 602 may be ultrasonically welded to the continuous backsheet 208A in some embodiments. The ground strip 602 may have a thickness (e.g., in the Y direction) of about 100 micrometers (pm) and a width (e.g., in the Z direction) of about 10 mm.

The continuous backsheet 208A additionally defines a slot 604 and includes one or more tabs 606A, 606B (collectively “tabs 606”). The slot 604 in some embodiments has a width (e.g., a dimension in the Z direction) in a range from about 3 to 8 mm and a length (e.g., a dimension in the X direction) in a range from about 75 to 200 mm. The slot 604 may include or correspond to the slot 320 of FIG. 3.

The tabs 606 in the illustrated embodiment include discrete tabs mechanically and electrically coupled to the continuous backsheet 208A. The tabs 606 may include or correspond to the second polarity contact described with respect to FIG. 3. The tabs 606 may include copper, hot-dipped copper, tin-coated copper, or other electrically-conductive and solderable material. During assembly in some embodiments, a lengthwise edge of each of the tabs 606 may be ultrasonically welded to the continuous backsheet 208A before the unwelded portion is bent to extend away from the continuous backsheet 208. The tabs 606 in some embodiments have a thickness (e.g., in the Y direction) of about 100 μm and a width (e.g., in the Z direction) before being bent of about 10 mm to about 14 mm.

FIG. 6B is a back perspective view of an embodiment 208B of the continuous backsheet 208, hereinafter “continuous backsheet 208B,” arranged in accordance with at least some embodiments described herein. The continuous backsheet 208B is similar in some respects to the continuous backsheet 208A. For example, the continuous backsheet 208B may include a ground strip (not shown), such as the ground strip 602 of FIG. 6A, mechanically and electrically coupled to the continuous backsheet 208B at one end, which ground strip may be included as part of or correspond to the end connection 316 of FIG. 3.

Similar to the continuous backsheet 208A, the continuous backsheet 208B additionally includes tabs 608A, 608B (collectively “tabs 608”) that are similar in some respects to the tabs 606. For example, both of the tabs 606, 608 are located on the continuous backsheet 208A, 208B at the end opposite the end that includes the ground strip and may include or correspond to the second polarity contact described with respect to FIG. 3. Additionally, both of the tabs 606, 608 extend away from the continuous backsheet 208A, 208B in a plane substantially normal to a plane defined by the continuous backsheet 208A, 208B. However, the tabs 608 of FIG. 6B are integral tabs integrally formed from the continuous backsheet 208B. Thus, the tabs 608 may include the same material(s) as the continuous backsheet 208B.

The continuous backsheet 208B additionally defines an edge slot 610 that may include or correspond to the slot 320 of FIG. 3.

FIG. 7 illustrates an example embodiment of the circuit card 302 of FIG. 3, arranged in accordance with at least one embodiment described herein. The circuit card 302 includes multiple converters 702 disposed thereon. In general, the converters 702 are configured to convert relatively high-current, low-voltage energy collectively generated by the PV cells 202 to a lower current and higher voltage. Accordingly, each of the converters 702 may include, for example, a boost converter, a buck-boost converter, a SEPIC converter, a Ćuk converter, or the like or any combination thereof.

The circuit card 302 additionally includes a digital controller 704 disposed thereon, a first polarity connector 706, one or more second polarity connectors 708, a first polarity terminal 710, and a second polarity terminal 712. It is assumed in the discussion that follows that the first polarity connector 706 and the first polarity terminal 710 respectively includes a positive connector (referred to hereafter as “positive connector 706”) and a positive terminal (referred to hereafter as “positive terminal 710”) and the second polarity connectors 708 and the second polarity terminal 712 respectively include negative connectors (referred to hereafter as “negative connectors 708”) and a negative terminal (referred to hereafter as “negative terminal 712”). In other embodiments, the polarities may be reversed. Optionally, the circuit card 302 further includes measurement circuitry 714, a protection relay 716, an opto-relay 718, and a radio frequency (RF)-emitting device 720, all of which are described in more detail in U.S. patent application Ser. No. 13/664,885, filed Oct. 31, 2012, which is incorporated herein by reference.

With combined reference to FIGS. 2B and 7, the positive terminal 710 may be electrically coupled to a PV module positive connector assembly 216 of the undermount assembly 212. Analogously, the negative terminal 712 may be electrically coupled to a PV module negative connector assembly 218 of the undermount assembly 212. The PV module positive connector assembly 216 may be configured to electrically couple the PV module 200 to a positive DC bus lead of a module-to-module bus that electrically couples multiple PV modules 200 in a parallel in a PV system. The PV module negative connector assembly 218 may be configured to electrically couple the PV module 200 to a negative DC bus lead of the module-to-module bus.

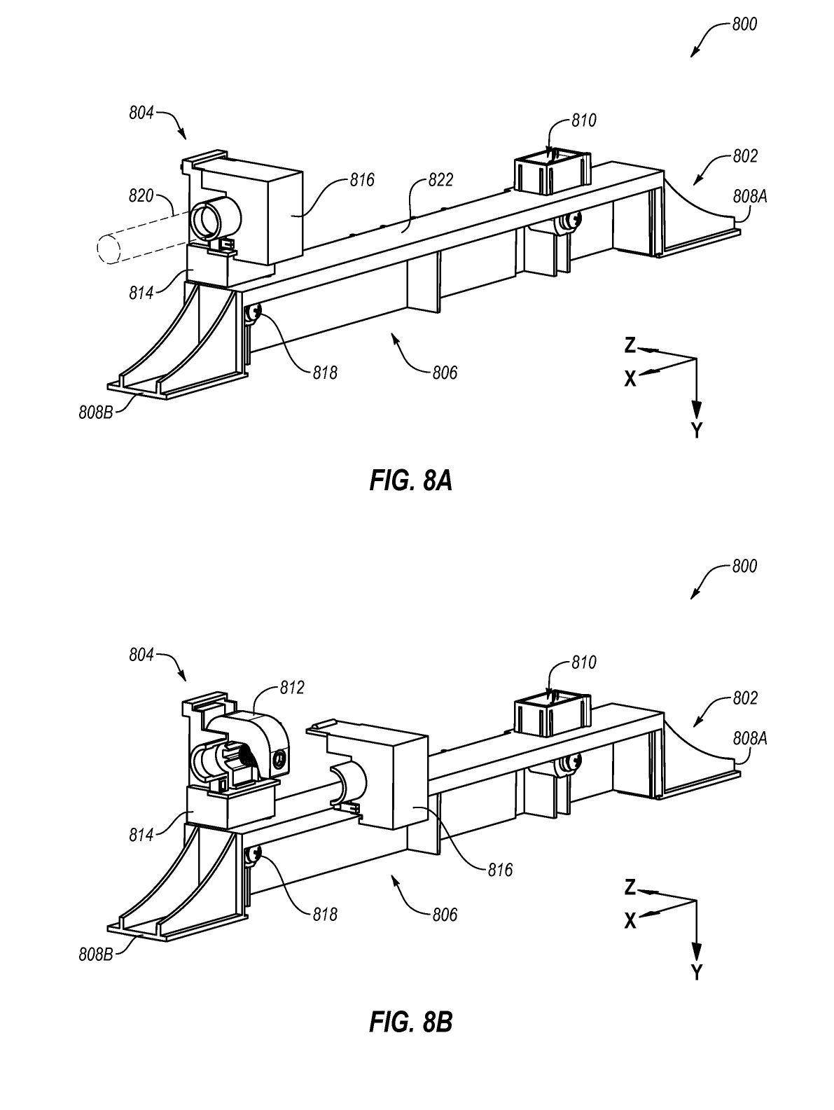

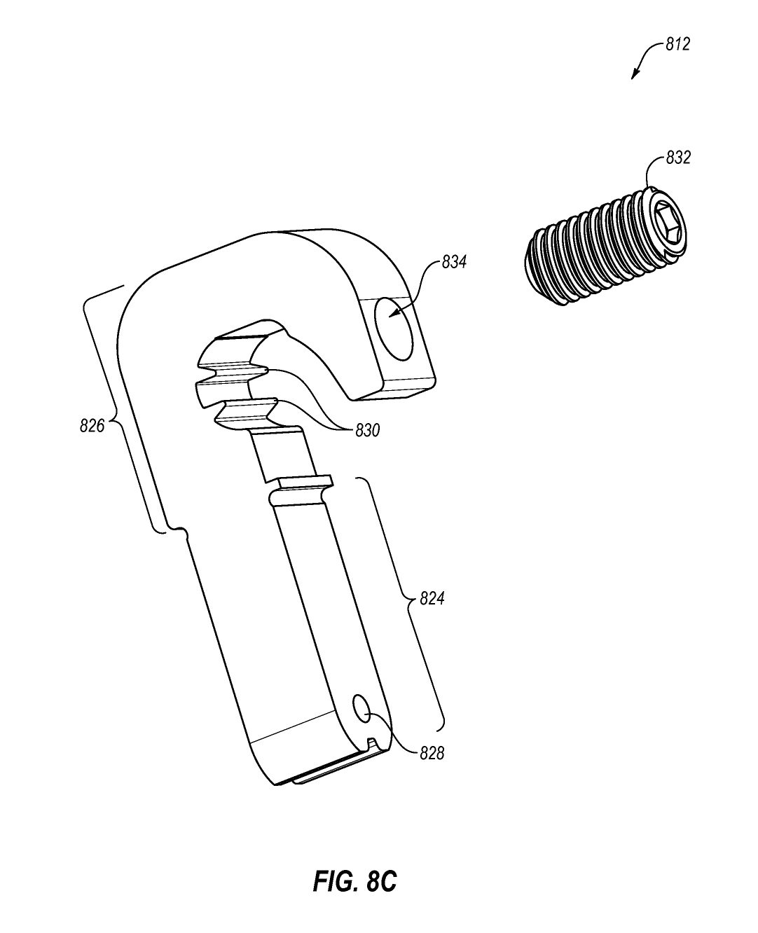

In the embodiment of FIG. 2B, the PV module positive and negative connector assemblies 216 and 218 are arranged to couple to the DC bus leads of the module-to-module bus with the DC bus leads arranged generally parallel to a plane of the PV module 200 (e.g., the XZ plane) and orthogonal to a plane of the undermount assembly 212 (e.g., the XY plane). As described with respect to FIGS. 8A-8C, in other embodiments, the PV module positive and negative connector assemblies 216 and 218 may be arranged to couple to the DC bus leads with the DC bus leads arranged generally parallel to the plane of the PV module 200 and parallel to the plane of the undermount assembly 212.

Returning to FIG. 7, each of the converters 702 is independently electrically coupled to the positive connector 706 via a corresponding one of multiple fuses 722. With combined reference to FIGS. 3 and 7, the buried first polarity contact 318 extends through the slot 320 in the continuous backsheet 208 and is soldered or otherwise electrically coupled to the positive connector 706 such that the PV cells 202 of the PV module 200 are electrically coupled through the buried first polarity contact 318, the positive connector 706 and the fuses 722 to each of the converters 702. As such, energy generated by each of the PV cells 202 may be receivable at any of the converters 702. In particular, the energy collectively generated by the PV cells 202 may be output onto the buried first polarity contact 318 and can then travel through the positive connector 706 to any of the converters 702 via a corresponding one of the fuses 722.

With combined reference to FIGS. 3 and 6A-7, each of the second polarity contacts of the continuous backsheet 208 (e.g., tabs 606A, 606B of the continuous backsheet 208A, or tabs 608A, 608B of the continuous backsheet 208B) extends from the continuous backsheet 208 and is soldered or otherwise electrically coupled to a corresponding one of the negative connectors 708 such that the circuit card 302 is grounded through the negative connectors 708 and the second polarity contacts to the continuous backsheet 208.

The digital controller 704 is communicatively coupled to each of the converters 702 via corresponding paired enable and pulse width modulation (PWM) lines 724. The converters 702 are each controlled independently of the others by the digital controller 704 via the paired enable and PWM lines 724. In some embodiments, the digital controller 704 is powered solely by energy generated by the PV module 200, or more particularly, by energy generated by the PV cells 202 of the PV module 200. During non-monotonically increasing or decreasing illumination conditions of the PV module 200, a discrete or integrated brown-out circuit (not shown) may be used to ensure the digital controller 704 is not corrupted.

In operation, energy generated by the PV cells 202 flows from the positive connector 706 through one of the fuses 722 into a corresponding one of the converters 702, which outputs energy with a relatively lower current and higher voltage onto an output bus 726 of the circuit card 302. Any number of converters 702 from zero up to all of the converters 702 may operate at a given time.

The output bus 726 is electrically coupled to outputs of each of the converters 702 and is thus common to all of the converters 702. The output bus 726 is coupled through the protection relay 716 to the positive terminal 710.

Current comes into the PV module 200 via the negative terminal 712 from the module-to-module bus mentioned in the discussion of the LED 214 of FIG. 2B when the PV module 200 is implemented in a multi-module PV system.

In some embodiments, the digital controller 704 collects status information about the PV module 200 and communicates it optically through the LED 214. The LED 214 may include a single-colored or multi-colored LED.

FIGS. 8A-8C illustrate portions of an undermount assembly 800, arranged in accordance with at least one embodiment described herein. The undermount assembly 800 is analogous to the undermount assembly 212 of FIG. 2B. As mentioned above, the PV module positive and negative connector assemblies 216 and 218 of FIG. 2B are arranged to couple to the DC bus leads of a module-to-module bus with the DC bus leads arranged generally parallel to a plane of the PV module 200 (e.g., the XZ plane) and orthogonal to a plane of the undermount assembly 212 (e.g., the XY plane) or to a length (e.g., the X direction) of the undermount assembly 212. In comparison, in FIGS. 8A-8C, the undermount assembly 800 includes PV module positive and negative connector assemblies 802 that may be arranged to couple to the DC bus leads with the DC bus leads arranged generally parallel to the plane of the PV module 200 and parallel to the plane (or the length) of the undermount assembly 212.

In more detail, the undermount assembly 800 illustrated in FIGS. 8A and 8B includes a housing 802 and a first PV module connector assembly 804 (hereinafter “first connector assembly 804”). The undermount assembly 800 additionally includes a second PV module connector assembly (hereinafter “second connector assembly) which is not illustrated in FIGS. 8A and 8B but which may generally be similar or identical to the first connector assembly 804. The first connector assembly 804 may include a PV module negative connector assembly and the second connector assembly may include a PV module positive connector assembly, or vice versa.

The housing 802 defines a cavity 806 within which a circuit card, such as the circuit card 302, may be disposed. Although not illustrated, the housing 802 may include a removable panel to enclose and environmentally protect the circuit card disposed within the cavity 806. The housing 802 includes one or more feet 808A, 808B that may be used to mechanically couple the undermount assembly 800 to the back surface of a PV module, such as the PV module 200.

The housing 802 defines two slots 810 (only one is visible in FIGS. 8A and 8B), one for the first connector assembly 804 and the other for the second connector assembly. The first connector assembly 804 includes a riser 812 (FIG. 8B) that extends through one of the slots 810 and that is electrically coupled to a second polarity terminal of the circuit card of the undermount assembly 800, such as the negative terminal 712 of FIG. 7. Similarly, the second connector assembly includes a riser that extends through the other of the slots 810 and that is electrically coupled to a first polarity terminal of the circuit card of the undermount assembly 800, such as the positive terminal 710 of FIG. 7.

The first connector assembly 804 may additionally include a nest 814, a cap 816, and a screw 818. A threaded shaft of the screw 818 may pass through a hole formed in the circuit card and a hole formed in a wall of one of the slots 810 of the housing 802 to engage a tapped hole formed in the riser 812 to secure the circuit card and the riser 812 to the housing 802 and to each other. When assembled in this manner, the riser 812 may be electrically coupled to the second polarity terminal of the circuit card, e.g., through the screw 818. The second connector assembly may be analogously configured.

FIG. 8A illustrates as an outline a portion of one wire 820 of a module-to-module bus connected to the first connector assembly 804. It can be seen from considering

FIGS. 2B and 8A together that if the undermount assembly 800 were used with the PV module 200 instead of the undermount assembly 212, the wire 820 would be arranged both parallel to a plane of the PV module (e.g., the XZ plane) and parallel to a length of the undermount assembly 800 (e.g., the X direction). A second wire of the module-to-module bus may be connected to the second connector assembly in an analogous manner.

The nest 814 extends rearward from a bottom surface 822 of the housing 802. The nest 814 may be a separate component from the housing 802 or may be an integral part thereof. The nest 814 defines a slot (not shown) in communication with a corresponding one of the slots 810 of the housing 802. The riser 812 passes through one of the slots 810 formed in the housing 802 and through the slot of the nest 814 into the cavity 806 of the housing 802. The cap 816 attaches to the nest 814 to enclose a C-shaped end of the riser 812 and a portion of the wire 820 within the nest 814 and the cap 816 to protect an electrical connection between the riser 812 and the wire 820 from environmental contaminants. The second connector assembly may include a nest, cap, and riser that are similarly configured with respect to each other and the second wire of the module-to-module bus.

With reference to FIG. 8C, the riser 812 includes a base 824 and a C-shaped end 826 opposite the base 824. The base 824 defines a tapped hole 828 that may be engaged by the threaded shaft of the screw 818 as indicated above. The C-shaped end 826 includes one or more insulation-penetrating members 830 and a clamping member 832. The C-shaped 826 may additionally define a tapped hole 834. The clamping member 832 may include a threaded set screw that threadably engages the tapped hole 834. The wire 820 may include an insulating jacket surrounding a metal wire. when the wire 820 is positioned between the insulation-penetrating members 830 and the clamping member 832 with the clamping member 832 threadably engaged within the tapped hole 834, the clamping member 832 may be tightened to urge the wire 820 against the insulation-penetrating members 830. As the clamping member 832 is tightened against the wire 820, eventually the insulation-penetrating members 830 may penetrate the insulating jacket of the wire 820 to electrically couple to the metal wire within.

The configuration of FIGS. 8A-8C in which the wires of the module-to-module bus are arranged parallel to the photovoltaic module and parallel to a length of the undermount assembly 800 may be implemented in residential installations or other installations where space beneath the PV modules is limited. The configuration of the wires of the module-to-module bus and its connections to the undermount assembly 800 of FIGS. 8A-8C may be more space efficient than the configuration of the wires of the module-to-module bus and its connections to the undermount assembly 212 of FIG. 2B.

The embodiments described herein may include the use of a special purpose or general-purpose computer including various computer hardware or software modules, as discussed in greater detail below.

Embodiments within the scope of the present invention also include computer-readable media for carrying or having computer-executable instructions or data structures stored thereon. Such computer-readable media can be any available media that can be accessed by a general purpose or special purpose computer. By way of example, and not limitation, such computer-readable media may include tangible computer-readable storage media including RAM, ROM, EEPROM, CD-ROM or other optical disk storage, magnetic disk storage or other magnetic storage devices, or any other medium which can be used to carry or store desired program code means in the form of computer-executable instructions or data structures and which can be accessed by a general purpose or special purpose computer. Combinations of the above should also be included within the scope of computer-readable media.

Computer-executable instructions comprise, for example, instructions and data which cause a general purpose computer, special purpose computer, or special purpose processing device to perform a certain function or group of functions. Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

As used herein, the term “module” or “component” can refer to software objects or routines that execute on the computing system. The different components, modules, engines, and services described herein may be implemented as objects or processes that execute on the computing system (e.g., as separate threads). While the system and methods described herein are preferably implemented in software, implementations in hardware or a combination of software and hardware are also possible and contemplated. In this description, a “computing entity” may be any computing system as previously defined herein, or any module or combination of modulates running on a computing system.

The present invention may be embodied in other specific forms without departing from its spirit or essential characteristics. The described embodiments are to be considered in all respects only as illustrative and not restrictive. The scope of the invention is, therefore, indicated by the appended claims rather than by the foregoing description. All changes which come within the meaning and range of equivalency of the claims are to be embraced within their scope.

What is claimed is:

1. A photovoltaic module, comprising:
a plurality of photovoltaic cells arranged in rows and columns, wherein the rows include a first row, a last row, and one or more intermediate rows between the first and last TOWS;
a continuous backsheet positioned behind the plurality of photovoltaic cells, wherein the continuous backsheet includes a ground plane for the plurality of photovoltaic cells and the continuous backsheet is electrically coupled between the first row of the plurality of photovoltaic cells and the last row of the plurality of photovoltaic cells;
a circuit card mechanically coupled to a back of the photovoltaic module, wherein the circuit card includes a first connector with a first polarity and a second connector with a second polarity opposite the first polarity; and
a buried first polarity contact positioned behind the plurality of photovoltaic cells, wherein the buried first polarity contact is electrically coupled to a back of each photovoltaic cell in one of the rows of the plurality of photovoltaic cells and wherein the buried first polarity contact extends through a slot formed in the continuous backsheet to electrical contact with the first connector of the circuit card.

2. The photovoltaic module of claim 1, further comprising a front plate in front of the plurality of photovoltaic cells and that is transparent to at least some wavelengths of light, wherein:
the plurality of photovoltaic cells are disposed between the front plate and the continuous backsheet;
the plurality of photovoltaic cells collectively form a photovoltaic cell layer; and
the front plate extends laterally beyond each of four edges of the photovoltaic cell layer by less than 14 millimeters (mm).

3. The photovoltaic module of claim 2, wherein a length of the front plate is less than 2.2 meters (m).

4. The photovoltaic module of claim 3, wherein the length of the front plate is between 1990 mm to 2020 mm and a width of the front plate is between 1265 mm to 1300 mm.

5. The photovoltaic module of claim 1, wherein a cell-to-cell gap between adjacent ones of the plurality of photovoltaic cells is equal to or less than 1.5 millimeters.

6. The photovoltaic module of claim 1, wherein the rows and columns of the plurality of photovoltaic cells include 25 rows and 8 columns of photovoltaic cells, 25 photovoltaic cells within each of the 8 columns are electrically connected together in series, 8 photovoltaic cells within each of the 25 rows are electrically connected together in parallel, and each of the plurality of photovoltaic cells is about 156.75 millimeters by 78.375 millimeters.

7. The photovoltaic module of claim 6, wherein under 1 sun of illumination, a power output collectively generated by the plurality of photovoltaic cells is at least 400 watts (W) and a voltage collectively generated by the plurality of photovoltaic cells is not more than 17 volts direct current (VDC).

8. The photovoltaic module of claim 1, further comprising:
an electrically-conductive material that coats a rear surface of each of the plurality of photovoltaic cells;
a plurality of busbars that electrically couples photovoltaic cells within each of the columns together in series, wherein between each serially adjacent pair of photovoltaic cells within each column the plurality of busbars includes a first busbar laterally to one side of the serially adjacent pair and a second busbar laterally to an opposite side of the serially adjacent pair, wherein each of the first and second busbars electrically couples a front of a first photovoltaic cell of the serially adjacent pair to the back of a second photovoltaic cell of the serially adjacent pair; and
a plurality of discrete conductive strips disposed behind the plurality of photovoltaic cells and that cooperates with the electrically-conductive material and the plurality of busbars to electrically couple photovoltaic cells within each of the rows together in parallel, wherein between each parallel adjacent pair of photovoltaic cells within each row the plurality of discrete conductive strips includes a discrete conductive strip coupled at one end to the first busbar of a first photovoltaic cell of the parallel adjacent pair and at an opposite end to the second busbar of a second photovoltaic cell of the parallel adjacent pair,
wherein within any given one of the first row or the one or more intermediate rows, the photovoltaic module lacks any single continuous conductor that forms any portion of a parallel electrical connection for the photovoltaic cells between three or more photovoltaic cells.

9. The photovoltaic module of claim 8, wherein each end of the discrete conductive strip is disposed behind a corresponding one of the first busbar or the second busbar to form first and second joints and wherein the continuous backsheet applies pressure of at least four pounds per sjoint on each of the first and second joints.

10. The photovoltaic module of claim 8, wherein the electrically-conductive material comprises aluminum paste and the plurality of discrete conductive strips comprises a plurality of pieces of conductive tape.

11. The photovoltaic module of claim 1, wherein each of the columns of photovoltaic cells includes N photovoltaic cells electrically connected together in series, the columns of photovoltaic cells include at least one column of a first type of photovoltaic cells and at least one column of a second type of photovoltaic cells, the first type of photovoltaic cells is different than the second type of photovoltaic cells, and each of the first and second types of photovoltaic cells is selected form the group consisting essentially of monocrystalline photovoltaic cells, polycrystalline photovoltaic cells, passive emitter rear contact (PERC) photovoltaic cells, and n-type photovoltaic cells.

12. The photovoltaic module of claim 1, wherein the plurality of photovoltaic cells includes photovoltaic cells with different energy conversion efficiencies.

13. The photovoltaic module of claim 12, wherein each of the columns of photovoltaic cells includes N photovoltaic cells electrically connected in series and the plurality of photovoltaic cells comprises a first column of N photovoltaic cells each with a first energy conversion efficiency and a second column of N photovoltaic cells each with a second energy conversion efficiency that is different than the first energy conversion efficiency.

14. The photovoltaic module of claim 13, wherein the first energy conversion efficiency is higher than the second energy conversion efficiency and the first row of N photovoltaic cells is located in an area of the photovoltaic module that receives more light than an area of the photovoltaic module that includes the second row of N photovoltaic cells.

15. The photovoltaic module of claim 1, further comprising a digital controller coupled to the circuit card and an optical signal source communicatively coupled to the digital controller, wherein optical signals emitted by the optical signal source are visible from a back of the photovoltaic module and the digital controller is configured to operate the optical signal source to emit optical signals comprising status information of the photovoltaic module.

16. The photovoltaic module of claim 15, wherein the status information indicates when a positive output and a negative output of the photovoltaic module are respectively connected to a positive direct current (DC) bus lead and a negative DC bus lead of a module-to-module bus configured to electrically couple multiple photovoltaic modules in parallel.

17. The photovoltaic module of claim 15, wherein the optical signal source includes a multi-colored LED configured to convey at least some of the status information by selectively using one of at least two different colors at a time.

18. The photovoltaic module of claim 1, wherein:
the continuous backsheet comprises aluminum or aluminum alloy with a temper of hard, full hard, or extra hard; and
the aluminum or aluminum alloy comprises aluminum or aluminum alloy in a commercially pure wrought family including in a 1000 series aluminum under International Alloy Designation System or in a 3000 series, 5000 series, or 6000 series alloy under the International Alloy Designation System.

19. The photovoltaic module of claim 1, wherein the continuous backsheet comprises a conductive substrate with an electrical isolation layer formed directly on at least one of a front surface or a rear surface of the conductive substrate.

20. The photovoltaic module of claim 19, wherein the electrical isolation layer formed directly on at least one of the front surface or the rear surface excludes cast plastic films attached to the conductive substrate with a separate adhesive.

21. The photovoltaic module of claim 19, further comprising one or both of:
a first electrical connector that electrically couples the first row of the plurality of photovoltaic cells to the continuous backsheet, wherein the first electrical connector is welded to the conductive substrate through the electrical isolation layer; or
a second electrical connector that electrically couples the continuous backsheet to the circuit card, wherein the second electrical connector is welded to the conductive substrate through the electrical isolation layer.

22. The photovoltaic module of claim 19, wherein the electrical isolation layer formed directly on at least one of the front surface or the rear surface of the conductive substrate comprises at least one of:
a polyvinylidene fluoride (PVDF) coating applied directly to a corresponding one of the front or rear surface of the conductive substrate;
a polyester coating applied directly to a corresponding one of the front or rear surface of the conductive substrate; or
an anodize coating applied directly to a corresponding one of the front or rear surface of the conductive substrate.

23. The photovoltaic module of claim 22, wherein the electrical isolation layer includes an ultraviolet (UV) stabilizer.

24. The photovoltaic module of claim 19, wherein:
the electrical isolation layer formed directly on at least one of the front surface or the rear surface of the conductive substrate comprises the electrical isolation layer formed only on the front surface of the conductive substrate and not on the rear surface of the conductive substrate;
the photovoltaic module further comprises a second electrical isolation layer laminated to the rear surface of the conductive substrate.

25. The photovoltaic module of claim 19, wherein:
the conductive substrate has a thickness between 0.04 millimeters (mm) to 0.2 mm;
each of the electrical isolation layer formed directly on at least one of the front surface or the rear surface of the conductive substrate has a thickness between 10 micrometers (μm) to 100 μm;
each of the electrical isolation layer formed directly on at least one of the front surface or the rear surface of the conductive substrate extends across the corresponding front or rear surface at least to each edge of the corresponding front or rear surface.

26. The photovoltaic module of claim 19, wherein the electrical isolation layer formed directly on at least one of the front surface or the rear surface of the conductive substrate comprises a baked electrical isolation layer formed directly on the front surface of the conductive substrate with reduced outgassing properties.

27. The photovoltaic module of claim 19, wherein the electrical isolation layer formed directly on at least one of the front surface or the rear surface of the conductive substrate is formed directly on the front surface of the conductive substrate and is white, transparent, or black.

28. The photovoltaic module of claim 19, wherein the electrical isolation layer formed directly on at least one of the front surface or the rear surface of the conductive substrate comprises:
a first electrical isolation layer formed directly on the front surface of the conductive substrate; and
a second electrical isolation layer formed directly on the rear surface of the conductive substrate,
wherein a color of the first electrical isolation layer is different than a color of the second electrical isolation layer.

29. The photovoltaic module of claim 1, further comprising an undermount assembly that includes the circuit card, wherein the undermount assembly further includes:
a housing within which the circuit card is disposed and that is mechanically coupled to the continuous backsheet;
a first riser that extends through a first slot formed in the housing and that is electrically coupled to a first polarity terminal of the circuit card; and
a second riser that extends through a second slot formed in the housing and that is electrically coupled to a second polarity terminal of the circuit card;
wherein each of the first riser and the second riser includes a C-shaped end to receive and secure therein a first wire or a second wire of a module-to-module bus that electrically couples multiple photovoltaic modules in parallel and wherein the C-shaped end is oriented to secure a corresponding one of the first wire or the second wire of the module-to-module bus parallel to the continuous backsheet and parallel to a length of the housing of the undermount assembly.

30. The photovoltaic module of claim 29, wherein:
each of the first riser and the second riser includes:
a base defining a tapped hole;
a C-shaped end opposite the base, wherein the C-shaped end includes an insulation-penetrating member and a clamping member;
the undermount assembly further comprises:
two nests that extend from a bottom surface of the housing, wherein each of the two nests is integral to the housing or separately attached thereto, each of the two nests defines a slot in communication with a different one of the slots of the housing, each of the first riser and the second riser passes through a slot defined in a corresponding one of the nests and a corresponding slot defined in the main body;
two caps, one each attached to a corresponding one of the two nests; and
two screws, one each securing the circuit card to a corresponding one of the first or second riser through the tapped hole defined in the base of the first or second riser;
the first and second wires of the module-to-module bus each have an insulating jacket;
each of the first and second wires of the DC bus is disposed within the C-shaped end of a corresponding one of the first or second riser without stripping the insulating jacket from the first or second wire during installation; and
the clamping member of each of the first or second riser is clamped during installation to clamp a corresponding one of the first or second wire against the insulation-penetrating member of the corresponding first or second riser such that the insulation-penetrating member penetrates the insulating jacket and electrically couples the corresponding first or second wire to the corresponding first or second riser;
the C-shaped end of each of first and second risers extends from a corresponding one of the two nests;
after electrically coupling the corresponding first or second wire to the corresponding first or second riser, each of the two caps is attached to a corresponding one of the two nests to enclose the C-shaped end of each of the first and second risers and a portion of each of the first and second wires where the insulating jacket has been penetrated within a corresponding one of the nests and a corresponding one of the caps and to protect a corresponding electrical connection between the C-shaped end and the corresponding first or second wire from environmental contaminants.
